(19) United States
(12) Patent Application Publication
(10) Pub. No.: US 2001/0002725 A1
(43) Pub. Date: Jun. 7, 2001

(54) Device for protecting touch-activated data terminals

(76) Inventors: Henri Pollet, Monchy-Humiere (FR); Philippe Robin, Cires Les Mello (FR)

Correspondence Address: LERNER AND GREENBERG, P. A., P.O. Box 2480, Hollywood, FL, 33022-2480, US

(21) Appl. No.: 09/728,338

(22) Filed: Dec. 1, 2000

(30) Foreign Application Priority Data
Dec. 1, 1999 (DE) 199 57 818.4
Jul. 28, 2000 (FR) 0009944

(51) Int. Cl. H01L 23/495

(52) U.S. Cl. 257/676

(57) ABSTRACT

A device for protecting a touch-activated data terminal device having a touch-activated input surface, with a protective foil affixable to the input surface by a holding mechanism, the protective foil fully covering the input surface, includes a multilayer structure receivable at the input surface. Thus, the multilayer structure can be accepted at the input surface or unwound from a material web supply. Also provided are a control console for a rotary printer, and a central control desk for a rotary printer and/or a folder.

### BACKGROUND OF THE INVENTION

1. Field of the Invention

The invention relates to a device for protecting touch-activated data terminals such as touch screens or other touch-activated input surfaces.

The published German Patent Document DE 19622323 C1 discloses a protective device for touch-activated data terminals, particularly keyboards, touch screens or other touch-activated input surfaces. A protective film web is electromotively transported by a film dispenser across the operating field of the data terminal into a protective film web chamber. The protective film completely covers the end surface of the data terminal device which is vulnerable to touching, whereby the instruction to advance the protective film is also inputted via a key or a sensor that likewise lies under the protective film. U.S. Pat. No. 5,550,564 is concerned with a cover for a touch-activated surface. A supply of transparent film is accepted on a dispensing reel, which cooperates with a take-up reel that is driven by a protective motor under and that winds the used, i.e., the soiled or contaminated, film supply and simultaneously transports new unused transparent material in front of the surface of the data terminal device. The advance is sensed by a pair of sensors, with the advance length being detected by an optical sensor, to which a rotation surface having at least one marking at the peripheral surface thereof is allocated. In this way, the web supply that must be unwound by the step motor can be determined, so that complete covering of the touch-activated surface with new unused cover material can be assured by suitably long actuation of the step motor.

It has been found that when touch-activated data terminals are used in printing operations, touch-activated surfaces become soiled or contaminated very quickly. The inks used in print shops dry very quickly and have a very highly tractive character even when they have formed only a thin skin on the surface but are still pasty underneath. When the pressman touches a touch-activated surface with ink on his fingers, then on the one hand, ink remains there in the path of the ink gap, and the ink develops a very strong adhesion when touched so that the protective film covering a touch-activated surface is lifted from the surface by the touch of the pressman, and in the extreme case, may even be torn, and on the other hand, it can be lifted in such a manner from the surface that is supposed to be protected, that the shielding thereof is no longer assured to a full extent.

### SUMMARY OF THE INVENTION

Starting from the aforedescribed state of the prior art and the disclosed technical problem, it is an object of the invention to provide a device for protecting touch-activated surfaces such as of data terminals, that is rugged, on the one hand, and that prevents the reel of protective material from being exhausted too quickly, on the other hand.

With the foregoing and other objects in view, there is provided in accordance with one aspect of the invention, a device for protecting a touch-activated data terminal device having a touch-activated input surface, with a protective foil affixable to the input surface by a holding mechanism, the protective foil fully covering the input surface, and comprising a multilayer structure receivable at the input surface.

In accordance with another feature of the invention, the multilayer structure is continuous and transparent, and is unwindable by a material web supply.

In accordance with a further feature of the invention, the multilayer structure includes at least one sublayer and one cover layer covering the sublayer.

In accordance with an added feature of the invention, the layers of the multilayer structure are realized so that they adhere to one another.

In accordance with an additional feature of the invention, the multilayer structure is realized as an insert surface element having a rectangular shape.

In accordance with yet another feature of the invention, the insert surface element is surrounded by a gripping bead.

In accordance with yet a further feature of the invention, the protective device includes an enclosure having an interior wherein the multilayer structure is received.

In accordance with yet an added feature of the invention, the multilayer structure has clamping corners.

In accordance with yet an additional feature of the invention, the protective device includes a slideway formed with an opening wherein the multilayer structure is accepted.

In accordance with still another feature of the invention, the protective device includes a supply reel whereon the multilayer structure is taken up as rolled material and fully covers an enclosure for a touch-activated surface.

In accordance with still a further feature of the invention, the protective device includes an adhesive layer for applying the multilayer structure to a web material.

In accordance with still an added feature of the invention, the web to which the multilayer structure is applied is taken up on a supply reel connectable to a drive.

In accordance with another aspect of the invention, there is provided a control console for a rotary printer having data terminal devices provided with touch-activated input surfaces, comprising a respective multilayer structure receivable at a respective input surface.

In accordance with a further aspect of the invention, there is provided a central control desk for at least one of a rotary printer and a folder having data terminal provided with touch-activated input surfaces, comprising a respective multilayer structure receivable at a respective input surface.

The advantages which are achievable with the construction according to the invention solution lie in the ability, offered by the multilayer structure, to remove the layer that has been soiled or contaminated most heavily by touching from the surface of the multilayer structure, so that a clean protective layer is exposed for the touch-activated surface that requires such covering. Depending upon the number of layers remaining on the multilayer structure, the transparency of the protective film increases as more layers are removed therefrom. Because the protective cover is constructed as a multilayer structure, it can be used until a minimum layer thickness is attained, which then indicates, for example, by a colored stripe that has been installed thereon, that it is necessary to replace the exhausted multilayer structure. The lifespan of individual multilayer structures is thereby significantly prolonged, which accounts considerably for the specific requirements of print shops with respect to the tractive character of accumulating ink.

In a further development of the inventive concept, the multilayer structure has at least two layers, the top layer of which can simply be removed by hand. In an advantageous development of the inventive concept, the layers that must be pulled off are formed with greater adhesive strength towards the base layer, so as to insure that during removal only the topmost layer, which is already soiled or contaminated, can be removed from the underlying fresh layer. The multilayer structure that covers the respective data terminal device can be constructed as a rectangular surface element that is to be inserted, and is realized with a flanged margin area. The margin region may be formed as a rounded gripping bead with rounded corner regions. The gripping bead facilitates the grasping of the multilayer structure and the removal thereof from the recess of the enclosure of the respective data terminal device, which surrounds the surface that requires protection.

Besides a flanging of the covering, the latter can also be constructed with a smooth surface. This is constructed with flexible clamping angles at the corner locations thereof, so that the covering is snapped into a recess formed in the enclosure of the data terminal device and fixed therein. The multilayer structure thus has requisite rigidity, so that the outermost layer can be pulled from the multilayer structure without any problem.

With the aid of a frame structure that is received at the front side of the touch-activated data terminal device, a multilayer structure according to the invention can be pushed in front of the touch-activated surface on the data terminal device that must be protected, either from above, from below, or from the side. Parts of the frame structure of the data terminal device, which fit the dimensions of the touch-activated surface, function as a slideway or sliding guide for the multilayer structure that is pushed in, and lend it the rigidity that is required in order to pull off the respective top layer.

Besides a finite configuration as a rectangular insert element which can be disposed in front of a touch-activated input surface element of a data terminal device, multilayer structures bordering on one another can be wound onto a continuously wound transparent material band or web, so that after a minimum layer thickness is reached, it can be moved from the surface that must be covered and fed to an empty reel that takes up the used portions of the multilayer structure. The reel for the used supply of multilayer structures which are accepted on the continuous web or band can advantageously be driven by a motor which transports each new portion of the multilayer structure in front of the touch-activated surface that must be covered and pulls this portion taut.

Other features which are considered as characteristic for the invention are set forth in the appended claims.

Although the invention is illustrated and described herein as embodied in a device for protecting touch-activated data terminals, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings, wherein:

### BRIEF DESCRIPTION OF THE DRAWINGS

FIG. 1 is a front, side and top perspective view of a multilayer structure with a flanged margin, the structure being seated in a depression formed in front of a touch-activated surface;

FIG. 2 is a view like that of FIG. 1 of the multilayer structure that is clamped into the depression surrounding the touch-activated surface;

FIG. 3 is a view like those of FIGS. 1 and 2 of another embodiment of the multilayer structure that is movable in a frame structure in front of the touch-activated surface; and

FIG. 4 is a view like those of FIGS. 1 to 3 of a further embodiment of the protective device according to the invention, wherein a continuous transparent web supply whereon mutually bordering successive multilayer structures are taken up, is conveyable from a supply reel to a further winding reel.

### DESCRIPTION OF THE PREFERRED EMBODIMENTS

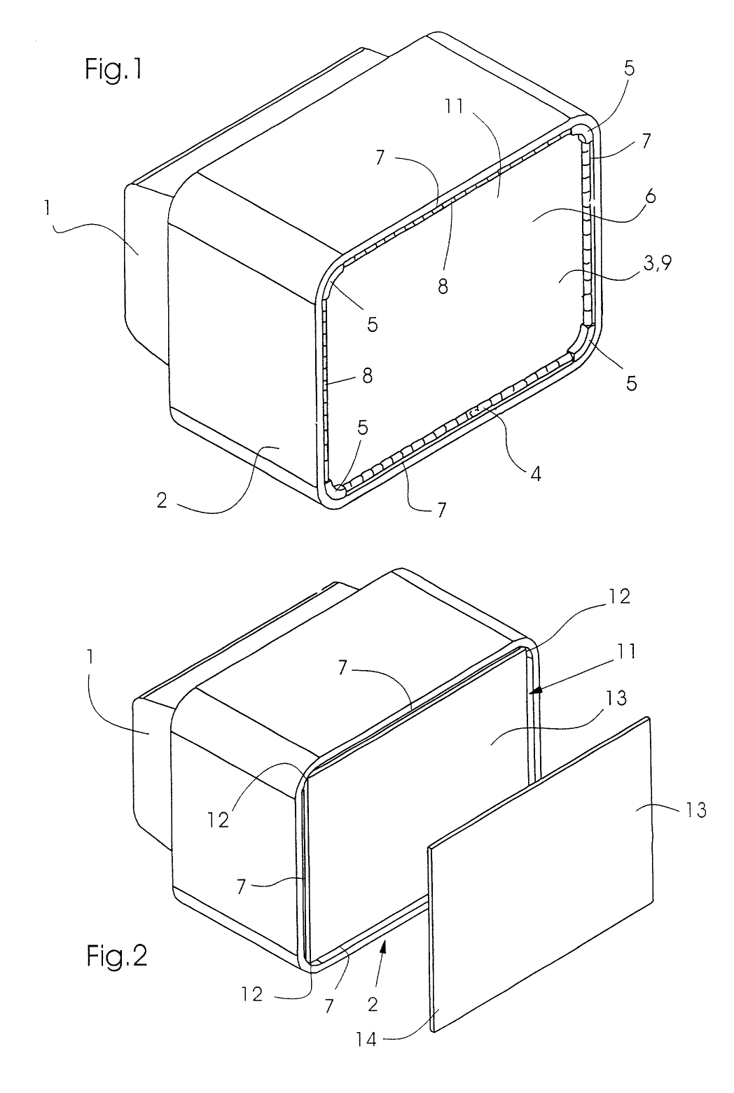

Referring now to the drawings and, first, particularly to FIG. 1 thereof, there is shown therein a multilayer structure that is inserted into a depression surrounding the surface requiring protection.

The representation in FIG. 1 is of a data terminal device 1 which is surrounded by an enclosure or frame 2. The enclosure 2 completely surrounds a surface 3 of the data terminal device 1, requiring protection or covering, and the interior 7 of the enclosure 2 extends over and beyond the planar surface 3 of the data terminal device 1. A surrounding surface of such construction frames a touch-activated surface 3 of the data terminal device 1 which is thus covered by a protective device equipped in accordance with the invention.

An insert surface member 11 covering the touch-activated surface 3 of the data terminal device 1 is inserted into the interior of the enclosure 2. The insert surface member 11 is preferably formed of several individual layers which adhere to one another. The outer edge of the insert surface member 11 is provided with a gripping bead 8 completely surrounding the insert surface 9. The gripping bead 8 can extend continuously about the outer margin of the insert surface member 11. On the other hand, the gripping bead 8 can also be constructed of at least approximately straight lateral portions 4, with the corners, respectively, remaining recessed or omitted. The lateral frame portions 4, i.e., the straight sides of the gripping bead 8, border the outer cover surface of the insert surface 9 so that it can be pulled off manually without difficulty from the insert surface 9 which is clamped into the interior 7 of the enclosure 2. The individual layers 14 of which the insert surface member 11 can be constructed can be transparent, i.e., completely translucent, but can also be produced with a matte surface. In the matte embodiment of the individual cover layers of the insert surface member 11, the number of layers that must be provided is limited by the luminous intensity with which the symbols provided on the touch-activated surface 3, for example, penetrate through the insert surface member 11 and can still be recognized on the outermost surface 9 of the insert surface member 11. According to the embodiment in FIG. 1, the gripping bead 8 can also be provided with corner pieces 5 at the ends thereof, with which the individual frame parts 4, the respective edges of which extend parallel to one another, can be connected to one another at the respective ends thereof.

FIG. 2 shows a multilayer structure which has been inserted into the enclosure of a monitor, for example, being clamped therein. In this embodiment of a protective device for touch-activated surfaces, the multilayer structure 13 has a rectangular construction. It may be made up of a plurality of individual layers which adhere to one another. The multilayer structure 13 is simply clamped within the interior 7 of the enclosure 2 of a data terminal device 1, it being possible to lock the structure in the interior 7 of the enclosure 2 at the four corners thereof in clamping angles 12. An outermost layer 14 of the multilayer structure 13 can be removed simply by pulling it from the layer of the multilayer structure 13 lying underneath it, the individual layers being so adherent to one another that only one layer, respectively, is able to be pulled away from the next underlying layer, the adhesive forces tending to increase as the layer thickness of the multilayer structure 13 diminishes. It is also possible, in this embodiment, to produce a multilayer structure 13 that is transparent or matted, depending upon the luminous intensity of a touch-activated surface 3.

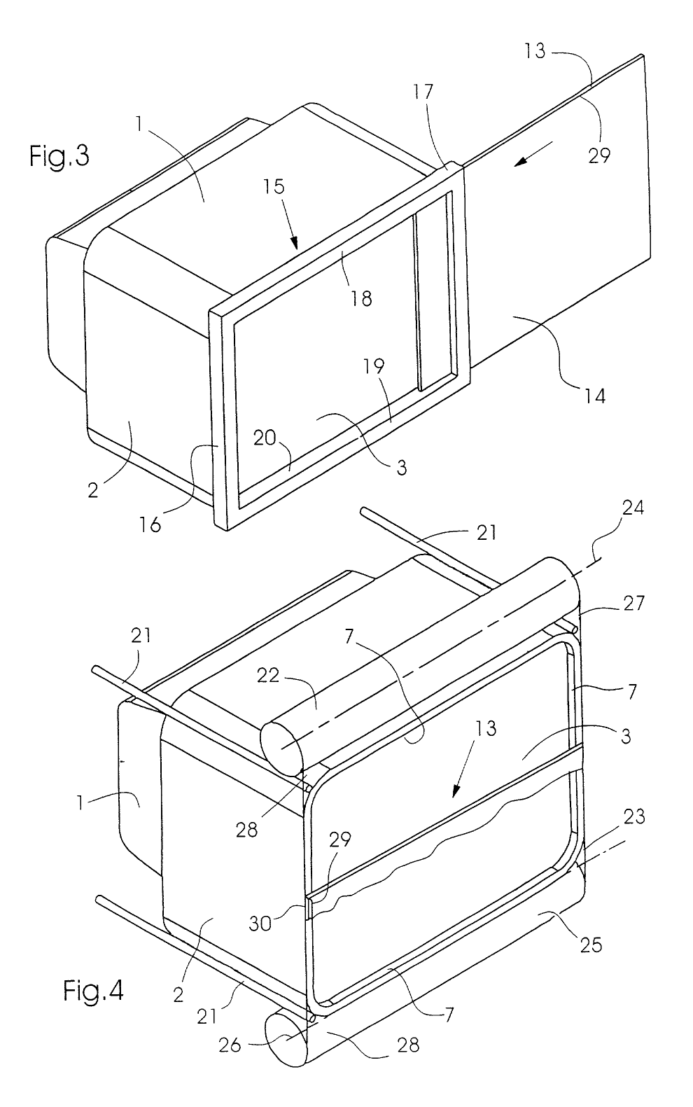

In the embodiment according to FIG. 3, at the front of a data terminal device 1, a frame structure 15 is provided, into which the multilayer structure is insertable. The frame structure 15 that is mounted in front of the enclosure 2 of the data terminal device 1 includes both a side part 16 and a side part having a slit-shaped opening 17, and both a top part 18 and a bottom part 19. The top surface 20 of the bottom part 19 can be constructed as a slideway 20 that supports the multilayer structure 13. The surface of the slideway 20 can either be made smooth or can be provided with a groove that improves the guidance of the multilayer structure 13 in the frame 15. The removal of the respective outermost cover layer 14 of the multilayer structure 13 is facilitated by constructing the cover layers 14, whether transparent or matted, so that the outer dimensions thereof are smaller than those the area that is surrounded by the frame structure 15. In this way, the respective uppermost cover layer 14 can easily be grasped by hand and removed from the multilayer structure 13, without any obstacle being presented by the frame structure 15 that surrounds the outer edges of the multilayer structure 13. The opening 17 serving for the insertion therethrough of the multilayer structure 13 into the frame 15 in front of the touch-activated surface 3 that must be protected, can be provided in one of the side parts 16 as well as in the top part 18. An opening in the bottom part 19 is likewise possible when two catches are provided which prevent the multilayer structure 13 from slipping out of the guides in a downward direction. The multilayer structure 13 can be constructed from a plurality of individual layers which are realized in such a manner that they adhere to one another. The individual layers adhering to one another are dimensioned so that only the respective outermost cover layer 14 can be pulled from the underlying layers of the multilayer structure 13. When a minimum layer thickness of the multilayer structure 13 is attained, this can be visually indicated to the user by a colored marking, for example, or in any other suitable manner.

Besides a transparent embodiment of the individual layers of the multilayer structure 13, this can also be realized with a matted surface. An alternating series of transparent and matted layers in a multilayer structure 13 can also be provided, so that even touch-activated surfaces 3 which are formed less luminous or with weak contrast can be effectively protected from ink or solvent residues. Using the layer sequence of transparent and matted cover layers 14, the multilayer structure 13 can be individually adapted or matched to a touch-activated surface 3, depending upon the luminosity of the touch-activated surface 3 that must be protected, and can be individually selected.

FIG. 4 shows a continuous web supply, whereon successive mutually abutting multilayer structures are taken up, the web supply being conveyable from a supply reel to a further winding reel.

The data terminal device 1, represented herein as a monitor, has a touch-activated surface 3, which is surrounded by an enclosure 2. Negative-pressure nozzle openings could also be provided at the data terminal device 1, in order to generate a vacuum so that a film can be sucked onto the surface of the screen. The nozzles for generating the negative pressure are provided as an option and are only mandatory when precisely dimensioned and specific coverage on the screen is to be implemented. With the holding mechanism of the data terminal 1 according to FIG. 4, it is possible to economize on actuating or adjusting surfaces on a control console, which are used particularly for inspecting flat print copies in printing operations. In addition to the automatic dimensional check of the print check strips or the measurement in the image in the rotary printer, pressmen remove a print run of individual copies in order individually to evaluate them visually. For this reason, the layout surface that is available on a control console of a printer control desk in a print shop, depending upon the copy size, is important.

On a web 27, adjoining multilayer structures 13 are disposed, vertical sections of which are represented in FIG. 4. The individual layers within the respective multilayer structure 13 adhere to one another through the intermediary of adhesive layers 29, the adhesive force of which increases as the number of cover layers 14 decreases. The multilayer structure 13 itself is secured on the continuous web supply 27 by an adhesive layer 30, which is formed so that the entire multilayer structure 13 that is located on the upper side of the web 27 cannot be inadvertently removed in its entirety from the upper side of the web. At the bottom of the data terminal device 1, a take-up reel 25 is provided, which is rotatable about a rotational axis 26 and can be driven via drive 23, so that when the cover layers of a multilayer structure 13 have been exhausted, this portion of the web can be wound up, and a new supply or a new multilayer structure 13 can be moved in front of the touch-activated surface 3 of a respective data terminal device 1. The web 27 can also be embodied in a single-layer structure. In this connection, it is entirely sufficient to wind up the soiled or contaminated layer onto a reel 28 and to move a clean batch 22 in front of the screen.

By using the drive 23, which is not otherwise represented in detail in FIG. 4, the material web 27 is stretched across the enclosure 2 of the touch-activated surface 3 of the data terminal device 1, so that the touch-activated surface 3 is covered by the multilayer structure 13. On the one hand, the tension of the material web supply 27 can be maintained by the drive 23 itself, and via an escapement in the supply reel 22 that can be moved about the axis of rotation 24. Both the take-up reel 25 and the supply reel 22 are rotatable about the respective axes 24 and 26 thereof. The drive 23 can be adjusted so that, depending upon the sequence of the multilayer structures 13 on the web supply 27, the multilayer structures 13 can be positioned in front of the touch-activated surface in such a manner as to ensure that the touch-activated surface 3 is completely covered by a multilayer structure 13 and thus protected against contact. As a result, when the top cover layer 14 has been used up, whether it is transparent or matted, it can be removed from the remaining multilayer structure 13 that is secured on the material web supply 27 by the adhesive layer 30.

As multilayer structures 13 that can be affixed to the top of a web supply 27 using adhesive layer 30, it is possible to use either transparent cover layers 14 only or such multilayer structures 13 including matted cover layers 14. Moreover, a multilayer structure 13 including an alternating cover layer sequence of transparent and matted layers which adhere to one another with different adhesive forces can also be received on the upper surface of the material web supply 27.

We claim:

1. A device for protecting a touch-activated data terminal device having a touch-activated input surface, with a protective foil affixable to the input surface by a holding mechanism, the protective foil fully covering the input surface, and comprising a multilayer structure receivable at the input surface.

2. The protective device according to claim 1, wherein said multilayer structure is continuous and transparent, and is unwindable by a material web supply.

3. The protective device according to claim 1, wherein said multilayer structure includes at least one sublayer and one cover layer covering said sublayer.

4. The protective device according to claim 1, wherein said layers of said multilayer structure are realized so that they adhere to one another.

5. The protective device according to claim 1, wherein said multilayer structure is realized as an insert surface element having a rectangular shape.

6. The protective device according to claim 5, wherein said insert surface element is surrounded by a gripping bead.

7. The protective device according to claim 5, including an enclosure having an interior wherein said multilayer structure is received.

8. The protective device according to claim 5, wherein said multilayer structure has clamping corners.

9. The protective device according to claim 1, including a slideway formed with an opening wherein said multilayer structure is accepted.

10. The protective device according to claim 2, including a supply reel whereon said multilayer structure is taken up as rolled material and fully covers an enclosure for a touch-activated surface.

11. The protective device according to claim 9, including an adhesive layer for applying said multilayer structure to a web material.

12. The protective device according to claim 11, wherein said web material to which said multilayer structure is applied is taken up on a supply reel connectable to a drive.

13. A control console for a rotary printer having data terminal devices provided with touch-activated input surfaces, comprising a respective multilayer structure receivable at a respective input surface.

14. A central control desk for at least one of a rotary printer and a folder having data terminal provided with touch-activated input surfaces, comprising a respective multilayer structure receivable at a respective input surface.
